(19) United States
(12) Patent Application Publication
(10) Pub. No.: US 2019/0172513 A1
(43) Pub. Date: Jun. 6, 2019

(54) MAGNETORESISTIVE ELEMENT AND ELECTRONIC DEVICE

(71) Applicant: SONY CORPORATION, TOKYO (JP)

(72) Inventor: EIJI KARIYADA, YAMAGATA (JP)

(21) Appl. No.: 16/323,620

(22) PCT Filed: Jul. 19, 2017
(86) PCT No.: PCT/JP2017/026098

§ 371 Date: Feb. 6, 2019

(30) Foreign Application Priority Data
Aug. 26, 2016 (JP) 2016-165417

(51) Int. Cl. G11C 11/16; H01F 10/16; H01F 10/32; G11B 5/39; H01L 43/10; H01L 43/08; H01L 43/02

(52) U.S. Cl. CPC G11C 11/161; H01F 10/16; H01F 10/32; H01L 43/02; H01L 43/10; H01L 43/08; G11B 5/39

(57) ABSTRACT

A magnetoresistive element 10 is formed by laminating a lower electrode 31, a first ground layer 21A including a non-magnetic material, a storage layer 22 having perpendicular magnetic anisotropy, an intermediate layer 23, a magnetization fixed layer 24, and an upper electrode 32. The storage layer 22 includes a magnetic material including at least a 3d transition metal element and a boron element in a composition. A second ground layer 21B is further included between the lower electrode 31 and the first ground layer 21A. The second ground layer 21B includes a material including at least one kind of element among elements constituting the storage layer in a composition.

### TECHNICAL FIELD

The present disclosure relates to a magnetoresistive element, and more specifically relates to, for example, a magnetoresistive element that is included in a memory element and an electronic device having such a magnetoresistive element.

### BACKGROUND ART

Various types of memory devices have been used in information processing systems of recent years as cache memories and storages. Development of non-volatile memories such as resistive RAMs (ReRAMs), phase-change RAMs (PCRAMs), and magnetoresistive RAMs (MRAMs) as memory devices of the next generation has been progressing. Among such non-volatile memories, an MRAM that uses a magnetoresistive element having a ferromagnetic tunnel junction (a magnetic tunnel junction (MTJ) element; which may also be referred to simply as a “magnetoresistive element” below) as a memory element has gained attention for the reason of being compact, achieving a high speed, allowing a virtually infinite number of rewrites, and the like, and a spin transfer torque-based magnetic random access memory (STT-MRAM) of a writing type using Spin-Momentum-Transfer (SMT) (a spin injection writing type) has been proposed.

A magnetoresistive element that stores information includes, for example, a magnetic material having perpendicular magnetic anisotropy. Such a magnetoresistive element includes a storage layer of which a magnetization direction is variable (which is also called a recording layer, a magnetization reversal layer, a magnetization free layer, a free layer, or a magnetic free layer), a magnetization fixed layer of which the magnetization is fixed (which is also called a pin layer or a magnetic pinned layer), and an intermediate layer including a tunnel insulation layer that is formed between the storage layer and the magnetization fixed layer. When a magnetization direction of the storage layer is parallel to a magnetization direction of the magnetization fixed layer (which is called a “parallel magnetization state”), the magnetoresistive element is in a low resistance state, and when the directions are anti-parallel (which is called an “anti-parallel magnetization state”), the magnetoresistive element is in a high resistance state. The difference in the resistance states is used to store information. Here, a larger amount of magnetization reversal current (which is also called a write current) is necessary at the time at which the state shifts from the parallel magnetization state (P state) to the anti-parallel magnetization state (AP state) than at the time at which the state shifts from the anti-parallel magnetization state (AP state) to the parallel magnetization state (P state).

However, structures of such magnetoresistive elements are classified into two types. That is, they are a bottom-pin structure in which a magnetization fixed layer is formed on a lower electrode and a storage layer is formed above the magnetization fixed layer with an intermediate layer interposed therebetween, and a top-pin structure in which a storage layer is formed on a lower electrode and a magnetization fixed layer is formed above the storage layer with an intermediate layer interposed therebetween. In addition, a magnetoresistive element is connected to a selection transistor, and an NMOS-type FET is normally used as a selection transistor.

At the time of information writing, a voltage and a current applied to a spin injection-type magnetoresistance effect element are determined depending on the driving ability of a selection transistor. Thus, asymmetry which is a difference in a value of a flowing drive current for a selection transistor between a case in which a current flows from a drain region to a source region and a case in which a current flows from a source region to a drain region exists. In a case in which an NMOS-type FET of which the drain region is connected to a spin injection-type magnetoresistance effect element is used as a selection transistor, when a current flowing from the drain region to the source region is denoted by I₁ and a current flowing from the source region to the drain region is denoted by I₂, the relation I₁>I₂ is satisfied.

When a magnetization direction of a storage layer is reversed such that the magnetization direction of the storage layer and a magnetization direction of a magnetization fixed layer shift from a parallel magnetization state to an anti-parallel magnetization state (information is rewritten) as described above, a larger amount of magnetization reversal current is necessary. The bottom-pin structure is frequently employed for magnetoresistive elements. However, when such information is rewritten in the bottom-pin structure, a current I₂ flows from a selection transistor to a spin injection-type magnetoresistance effect element, and thus there may be some cases in which there is little tolerance regarding a current value of the NMOS-type FET and rewriting of information is difficult (refer to Non-Patent Literature 1).

### CITATION LIST

### Non-Patent Literature

Non-Patent Literature 1: Hiroki Koike, et al., “Wide operational margin capability of 1 Kbit spin-transfer-torque memory array chip with 1-PMOS and 1-bottom-pin-magnetic-tunnel-junction type cell,” Japanese Journal of Applied Physics 53, 04ED13 (2014)
Non-Patent Literature 2: Kay Yakushiji, et al., “High Magnetoresistance Ratio and Low Resistance-Area Product in Magnetic Tunnel Junctions with Perpendicularly Magnetized Electrodes,” Applied Physics Express 3 (2010) 053003

### DISCLOSURE OF INVENTION

### Technical Problem

Meanwhile, the problem of deficiency in the tolerance in a rewrite current value is resolved by employing the top-pin structure. However, in order to maintain perpendicular magnetic anisotropy of the storage layer formed on the lower electrode, it is necessary to form a ground layer between the lower electrode and the storage layer. For example, Non-Patent Literature 2 discloses a technology of forming a ground layer including Ru on a lower electrode and forming a magnetic ground layer including Co—Pt having perpendicular magnetic anisotropy between the Ru ground layer and a storage layer including Co—Fe—B. When the magnetic ground layer having perpendicular magnetic anisotropy is disposed adjacent to the storage layer as described above, the magnetic ground layer and the storage layer are magnetically coupled, and thus perpendicular magnetic anisotropy of the storage layer is strengthened and a coercive force of the storage layer is improved. However, when this is compared with a structure with no magnetic ground layer, there is a problem of a write current value increasing.

Therefore, the present disclosure aims to provide a magnetoresistive element that has a configuration and a structure that can avoid the problem of an increasing write current value even when a ground layer is formed and an electronic device having such a magnetoresistive element.

### Solution to Problem

A magnetoresistive element according to a first aspect of the present disclosure to achieve the object described above is formed by laminating a lower electrode, a first ground layer including a non-magnetic material, a storage layer (which is also called a recording layer, a magnetization reversal layer, a magnetization free layer, or a free layer) having perpendicular magnetic anisotropy, an intermediate layer, a magnetization fixed layer, and an upper electrode. The storage layer includes a magnetic material including at least a 3d transition metal element and a boron element in a composition. A second ground layer is further included between the lower electrode and the first ground layer. The second ground layer includes a material including at least one kind of element among elements constituting the storage layer in a composition.

A magnetoresistive element according to a second aspect of the present disclosure to achieve the object described above is formed by laminating a lower electrode, a first ground layer including a non-magnetic material, a storage layer, an intermediate layer, a magnetization fixed layer, and an upper electrode. The storage layer has perpendicular magnetic anisotropy. A second ground layer is further included between the lower electrode and the first ground layer. The second ground layer has in-plane magnetic anisotropy or non-magnetism.

The electronic device of the present disclosure for achieving the above-described objectives has a magnetoresistive element according to the first and second aspects of the present disclosure.

### Advantageous Effects of Invention

In the magnetoresistive element according to the first aspect of the present disclosure, the second ground layer included between the lower electrode and the first ground layer includes a material including at least one element among elements constituting the storage layer in a composition. In addition, in the magnetoresistive element according to the second aspect of the present disclosure, the second ground layer included between the lower electrode and the first ground layer has in-plane magnetic anisotropy or non-magnetism. In addition, by providing the second ground layer as described above, a crystal orientation of the first ground layer is improved, as a result, perpendicular magnetic anisotropy of the storage layer formed on the first ground layer can be improved, and thus, while a coercive force of the storage layer can be increased, the problem of a high write current value can be avoided. Note that the effects described in the present specification are merely illustrative, not limitative, and additional effects may be exhibited.

### BRIEF DESCRIPTION OF DRAWINGS

FIG. 1 is a conceptual diagram of a magnetoresistive element according to Embodiment 1.

FIG. 2 is a schematic partial cross-sectional diagram of the magnetoresistive element according to Embodiment 1 including a selection transistor.

FIG. 3 is an equivalent circuit diagram of magnetoresistive elements and a memory cell unit according to Embodiment 1 including the selection transistors.

FIG. 4 is a conceptual diagram of a magnetoresistive element according to Embodiment 2.

FIG. 5A is a graph showing a relation between a thickness (T₂) of a second ground layer and retention power of a storage layer for magnetoresistive elements according to Embodiment 1 and Comparative Example 1A, and FIG. 5B is a graph showing a relation between a thickness (T₁) of a first ground layer and retention power of the storage layer.

FIG. 6A and FIG. 6B are a schematic perspective diagram illustrating a cut part of a composite magnetic head according to Embodiment 3 and a schematic cross-sectional diagram of the composite magnetic head according to Embodiment 3, respectively.

FIG. 7A and FIG. 7B are conceptual diagrams of a spin injection-type magnetoresistance effect element to which spin injection magnetization reversal is applied.

FIG. 8A and FIG. 8B are conceptual diagrams of a spin injection-type magnetoresistance effect element to which spin injection magnetization reversal is applied.

### MODE(S) FOR CARRYING OUT THE INVENTION

The present disclosure will be described on the basis of embodiments with reference to the drawings, but, the present disclosure is not limited to the embodiments, and the various numerical values and materials of the embodiments are merely examples. Note that description will be provided in the following order.

1. Overall description of magnetoresistive element according to first and second aspects of present disclosure and electronic device of present disclosure
2. Embodiment 1 (magnetoresistive element according to first and second aspects of present disclosure and electronic device of present disclosure)
3. Embodiment 2 (modification of Embodiment 1)
4. Embodiment 3 (electronic device with magnetoresistive element described in Embodiment 1 or Embodiment 2)

### 5. Others

### <Overall Description of Magnetoresistive Element According to First and Second Aspects of Present Disclosure and Electronic Device of Present Disclosure>

In the magnetoresistive element according to the first aspect of the present disclosure and the magnetoresistive element according to the first aspect of the present disclosure included in an electronic device of the present disclosure, a second ground layer can have in-plane magnetic anisotropy or non-magnetism.

In the magnetoresistive element according to the first aspect of the present disclosure including the above-described preferred form, a magnetoresistive element according to first and second aspects of the present disclosure including the above-described preferred form included in an electronic device of the present disclosure, and a magnetoresistive element according to the second aspect of the present disclosure (which will be collectively referred to as a “magnetoresistive element of the present embodiment and the like” below), a storage layer includes Co—Fe—B, and the boron atom content of the second ground layer can be in the range of 10 atomic % to 50 atomic %. By regulating a lower limit value of the boron atom content of the second ground layer such that it is such a value, a crystal orientation of a first ground layer is further improved by the formation of the second ground layer, and as a result, perpendicular magnetic anisotropy of the storage layer can be more reliably improved. In addition, by regulating an upper limit value of the boron atom content of the second ground layer such that it is such a value, there is no concern of the problem that strength of a target material used to form the second ground layer using a sputtering method decreases.

In the magnetoresistive element of the present disclosure and the like including the above-described preferred forms, the second ground layer includes a Co—Fe—B layer, and the first ground layer can include one material selected from a group consisting of tantalum, molybdenum, tungsten, titanium, magnesium, and magnesium oxide. This configuration will be called a “magnetoresistive element with a first configuration” for the sake of convenience. In addition, in the magnetoresistive element with the first configuration, when a thickness of the second ground layer is denoted by T₂ and a thickness of the storage layer is denoted by T₀, it is possible to satisfy T₀≤T₂, and furthermore, it is preferable to satisfy T₂≤3 nm, for example, 1 nm≤T₂≤3 nm. By setting T₀≤T₂, the crystal orientation of the first ground layer is further improved, and as a result, perpendicular magnetic anisotropy of the storage layer can be further strengthened. Meanwhile, by setting T₂≤3 nm, the second ground layer exhibits appropriate in-plane magnetic anisotropy, and as a result, perpendicular magnetic anisotropy of the storage layer can be further strengthened, and a coercive force of the storage layer can be further improved. In addition, by regulating the thickness T₂ of the second ground layer as described above, in-plane magnetic anisotropy and non-magnetism of the second ground layer can be reliably achieved. Note that, when a magnetic field is applied to the Co—Fe—B layer in the normal direction, perpendicular magnetic anisotropy is exhibited when the thickness of the Co—Fe—B layer is greater than or equal to 1 nm and less than 1.5 nm, and in-plane magnetic anisotropy is exhibited when the thickness is greater than or equal to 1.5 nm in general.

Furthermore, in the magnetoresistive element with the first configuration including the above-described preferred forms, a third ground layer can be formed between a lower electrode and the second ground layer. Here, the third ground layer can include one kind of material selected from a group consisting of tantalum, molybdenum, tungsten, titanium, magnesium, and magnesium oxide, or the third ground layer can include the same material as the material that forms the first ground layer. By forming the third ground layer, a crystal orientation of the second ground layer can be improved, as a result, a crystal orientation of the first ground layer can be further improved, and perpendicular magnetic anisotropy of the storage layer can be further strengthened.

Alternatively, in the magnetoresistive element of the present disclosure including the above-described preferred forms and the like, the second ground layer can be formed by alternatively laminating first material layers and second material layers. This configuration will be referred to as a “magnetoresistive element with a second configuration” for the sake of convenience. In addition, in the magnetoresistive element with the second configuration, the first material layer includes a Co—Fe—B layer, and the second material layer can include a non-magnetic material layer. Furthermore, in the magnetoresistive element with the second configuration of the above-described configurations, the second material layer can include one kind of material selected from a group consisting of tantalum, molybdenum, tungsten, titanium, magnesium, and magnesium oxide. Furthermore, in the magnetoresistive element with the second configuration of the above-described configurations, the material forming the first ground layer and the material forming the second material layer can be the same. Furthermore, in the magnetoresistive element with the second configuration of the above-described configurations, when a thickness of the second ground layer is denoted by T₂′, it is preferable to satisfy 3 nm≤T₂′, a crystal orientation of the first ground layer is further improved, and as a result, perpendicular magnetic anisotropy of the storage layer can be further strengthened. An upper limit of T₂′ and the number of first material layers and second material layers are not particularly limited, a thickness (height) of the laminated structure is defined on the basis of processability and thicknesses of various layers, and thus the value of T₂′ and the number of first material layers and second material layers may be determined in accordance with the thickness (height) of the laminated structure. In addition, when a thickness or the number of first material layers and second material layers increases, a processing time such as a film formation time of the first material layers and the second material layers is lengthened, and thus these values should be determined taking the processing time into consideration. For example, 10 nm can be exemplified as the upper limit of T₂′. When a thickness of the first material layer is denoted by T_{2-A}′ and a thickness of the second material layer is denoted by T_{2-B}′, although a relationship therebetween is not limited to the following, it is preferable to satisfy

0.2≤T_{2-A}′/T_{2-B}′≤5.

In addition, the thickness T_{2-A}′ of the first material layer may be thinner than a thickness T₀ of the storage layer, that is, it is preferable to satisfy

T_{2-A}′<T₀.

In the magnetoresistive element of the present disclosure including the above-described various preferred forms and configurations, the magnetoresistive element with the first configuration, the magnetoresistive element with the second configuration, and the like, when a thickness of the first ground layer is denoted by T₁, it is preferable to satisfy 1 nm≤T₁≤4 nm. By satisfying 1 nm≤T₁, for example, the influence of the in-plane magnetic anisotropy of the second ground layer exerted on perpendicular magnetic anisotropy of the storage layer decreases. Meanwhile, by satisfying T₁≤4 nm, a crystal orientation of the first ground layer is further improved, and as a result, perpendicular magnetic anisotropy of the storage layer can be more reliably improved.

In the magnetoresistive element of the present disclosure including the above-described various preferred forms and configurations, the magnetoresistive element with the first configuration, the magnetoresistive element with the second configuration, and the like, a magnetization direction of the storage layer changes in accordance with information to be stored, and an axis of easy magnetization of the storage layer is parallel to the laminating direction of the laminated structure including ground layers, the storage layer, an intermediate layer, and a magnetization fixed layer (i.e., of a perpendicular magnetization type). In addition, in this case, the magnetoresistive element can be a magnetoresistive element of a perpendicular magnetization type for writing and erasing information by reversing magnetization of the storage layer using spin torque (spin injection-type magnetoresistance effect element). Here, the ground layers include the first ground layer and the second ground layer, or include the first ground layer, the second ground layer, and the third ground layer.

In the magnetoresistive element of the present disclosure including the above-described various preferred forms, the magnetoresistive element with the first configuration, the magnetoresistive element with the second configuration, and the like (which may be referred to simply as an “element of the present disclosure” below), the crystallinity of the storage layer and the magnetization fixed layer is basically arbitrary, and may be poly-crystalline, mono-crystalline, or amorphous.

In the element of the present disclosure, although Co—Fe—B is exemplified as a material that forms the storage layer, broadly, the storage layer can include a metallic material (an alloy or a compound) including cobalt, iron, nickel, and boron. Specifically, for example, Fe—B or Co—B can be exemplified in addition to Co—Fe—B. Furthermore, in order to further increase perpendicular magnetic anisotropy, a heavy rare earth element such as terbium (Tb), dysprosium (Dy), holmium (Ho), or the like may be added to the alloy. A non-magnetic element may be added to the material forming the storage layer. In addition, due to the addition of the non-magnetic element, the effects of improved heat resistance attributable to prevention of diffusion, an increase in a magnetoresistance effect, an increase in a withstand voltage resulting from flattening, and the like are obtained. As non-magnetic elements to be added, C, N, O, F, Li, Mg, Si, P, Ti, V, Cr, Mn, Ni, Cu, Ge, Nb, Ru, Rh, Pd, Ag, Ta, Ir, Pt, Au, Zr, Hf, W, Mo, Re, and Os may be exemplified.

The storage layer can also have a single layer configuration, a laminated structure in which ferroelectric material layers having different compositions are laminated, or a laminated configuration in which a ferroelectric material layer and a non-magnetic layer are laminated. Alternatively, a ferroelectric material layer and a soft magnetic material layer may be laminated, or a plurality of ferroelectric material layers can be laminated having a soft magnetic material layer or a non-magnetic material layer interposed therebetween. In a case in which ferroelectric material layers are laminated having a non-magnetic material layer interposed therebetween, a relationship in magnetic strength between the ferroelectric material layers can be adjusted, and thus a magnetization reversal current of the spin injection-type magnetoresistance effect element can be prevented from increasing. Here, as ferromagnetic materials other than the above-described materials for forming the storage layer, a ferromagnetic material such as nickel (Ni), iron (Fe), or cobalt (Co), an alloy of these ferromagnetic materials (e.g., Co—Fe, Co—Fe—Ni, Fe—Pt, Ni—Fe, etc.), or an alloy obtained by adding gadolinium (Gd) to the aforementioned alloys, an alloy obtained by incorporating a non-magnetic element (e.g., tantalum, chromium, platinum, silicon, carbon, nitrogen, etc.) in these alloys, an oxide including one or more kinds of Co, Fe, and Ni (e.g., ferrite: Fe—MnO, etc.), a group of intermetallic compounds called half metallic ferromagnetic materials (Heusler alloys: NiMnSb, Co₂MnGe, Co₂MnSi, Co₂CrAl, etc.), and oxides (e.g., (La, Sr)MnO₃, CrO₂, Fe₃O₄, etc.) can be exemplified. In addition, as a material of the non-magnetic material layer, Ru, Os, Re, Ir, Au, Ag, Cu, Al, Bi, Si, B, C, Cr, Ta, Pd, Pt, Zr, Hf, W, Mo, Nb, V, or an alloy thereof can be exemplified.

Furthermore, in the element of the present disclosure including the above-described various preferred forms, it is preferable for the intermediate layer to include a non-magnetic material. That is, the element of the present disclosure is a spin injection-type magnetoresistance effect element and exhibits a tunnel magnetoresistance (TMR) effect. That is, the element of the present disclosure has a structure in which the intermediate layer including a non-magnetic material that functions as a tunnel insulation layer is interposed between a magnetization fixed layer including a magnetic material and the storage layer including a magnetic material layer. The intermediate layer cuts the magnetic coupling between the storage layer and the magnetization fixed layer, is responsible for causing a tunnel current to flow, and is also called a tunnel insulation layer.

Here, as non-magnetic materials for forming the intermediate layer, magnesium oxide (MgO), magnesium nitride, magnesium fluoride, aluminum oxide (AlO_{X}), aluminum nitride (AlN), silicon oxide (SiO_{X}), silicon nitride (SiN), various insulating materials, dielectric materials, and semiconductor materials such as TiO₂, Cr₂O₃, Ge, NiO, CdO_{X}, HfO₂, Ta₂O₅, Bi₂O₃, CaF, SrTiO₃, AlLaO₃, Mg—Al₂—O, Al—N—O, BN, and ZnS can be exemplified. It is preferable for an area resistance value of the intermediate layer to be about several tens of Ω·μm² or lower. In a case in which the intermediate layer includes magnesium oxide (MgO), it is desirable for the MgO layer to be crystallized, and more desirable to have a crystal orientation in the (001) direction. In addition, in the case in which the intermediate layer includes magnesium oxide (MgO), it is desirable for a thickness thereof to be 1.5 nm or smaller.

The intermediate layer can be obtained by oxidizing or nitrifying, for example, a metal layer formed using a sputtering method. More specifically, in a case in which aluminum oxide (AlO_{X}) or magnesium oxide (MgO) is used as an insulating material to form the intermediate layer, for example, a method of oxidizing aluminum or magnesium formed using a sputtering method in the atmosphere, a method of plasma-oxidizing aluminum or magnesium formed using a sputtering method, a method of IPC-plasma-oxidizing aluminum or magnesium formed using a sputtering method, a method of naturally oxidizing aluminum or magnesium formed using a sputtering method in oxygen, a method of oxidizing aluminum or magnesium formed using a sputtering method with oxygen radicals, a method of radiating ultraviolet rays to aluminum or magnesium formed using a sputtering method when it is naturally oxidized in oxygen, a method of forming a film of aluminum or magnesium using a reactive sputtering method, or a method of forming a film of aluminum oxide (AlO_{X}) or magnesium oxide (MgO) using a sputtering method can be exemplified.

Since a magnetization direction of the magnetization fixed layer is a reference for information, the magnetization direction should not be changed by recording or reading of information, but it is not necessary for the direction to be fixed to a specific direction, and a configuration or a structure in which it is more difficult to change this magnetization direction than that of the storage layer may be provided by setting a greater coercive force than that of the storage layer, thickening the thickness, or increasing a magnetic damping constant.

In the element of the present disclosure including the above-described various preferred forms, the magnetization fixed layer can have a laminated ferromagnetic structure (which is also called a laminated ferri-pin structure) in which at least two magnetic material layers are laminated. The laminated ferromagnetic structure is a laminated structure with anti-ferromagnetic coupling, that is, a structure in which interlayer exchange coupling of two magnetic material layers (a reference layer and a fixed layer) is anti-ferromagnetic, which is also called synthetic anti-ferromagnetic coupling (Synthetic Antiferromagnet or SAF) indicating a structure in which interlayer exchange coupling of the two magnetic material layers (the reference layer and the fixed layer) is anti-ferromagnetic or ferromagnetic depending on a thickness of a non-magnetic layer provided between the two magnetic material layers, which is reported in, for example, Physical Review Letters, S. S. Parkin et. al, 7 May, pp. 2304 to 2307 (1990). A magnetization direction of the reference layer is a magnetization direction serving as a reference for information to be stored in the storage layer. One magnetic material layer (the reference layer) included in the laminated ferromagnetic structure is located on the storage layer side. By employing a laminated ferromagnetic structure for the magnetization fixed layer, it is possible to reliably cancel out asymmetry in thermal stability in an information writing direction and to improve stability in spin torque. In the laminated ferromagnetic structure, for example, a Co—Fe—B alloy can be exemplified as a material forming the reference layer, and a Co—Pt alloy can be exemplified as the fixed layer. Alternatively, the magnetization fixed layer can include a Co—Fe—B alloy layer, and a value in the range from 0.5 nm to 30 nm can be exemplified as a thickness of the magnetization fixed layer.

The above-described various layers can be formed using, for example, a sputtering method, an ion beam deposition method, a physical vapor deposition method (PVD method) exemplified as a vacuum evaporation method, or a chemical vapor deposition method (CVD method) typified by an atomic layer deposition (ALD) method. In addition, patterning of these layers can be performed using a reactive ion etching method (RIE method), or an ion milling method (ion beam etching method). It is preferable to continuously form various layers in a vacuum device and then to perform patterning thereon.

In the element of the present disclosure, if a magnetization reversal current flows from the storage layer to the magnetization fixed layer in an anti-parallel magnetization state, the magnetization of the storage layer is reversed due to spin torque acting due to electrons injected from the magnetization fixed layer to the storage layer, and thus the magnetization direction of the storage layer, the magnetization direction of the magnetization fixed layer (specifically, the reference layer), and the magnetization direction of the storage layer are arranged in parallel. On the other hand, if a magnetization reversal current flows from the magnetization fixed layer to the storage layer in a parallel magnetization state, the magnetization of the storage layer is reversed due to spin torque acting due to electrons flowing from the storage layer to the magnetization fixed layer, and thus the magnetization direction of the storage layer and the magnetization direction of the magnetization fixed layer (specifically, the reference layer) become in an anti-parallel magnetization state.

Although it is desirable for the three-dimensional shape of the storage layer to be a tubular shape (cylindrical shape) from the viewpoint of securing easy processability and uniformity in directions of the axis of easy magnetization of the storage layer, the disclosure is not limited thereto, and the shape can be a triangular cylinder, a square cylinder, a hexagonal cylinder, an octagonal cylinder, or the like (including one having rounded sides or side ridges), or elliptic cylinder. It is preferable for an area of the storage layer to be, for example, 0.01 μm² or smaller from the viewpoint of easy reversal of the direction of magnetization by a low magnetization reversal current. When a magnetization reversal current flows in the laminated structure from a lower electrode to an upper electrode or from the upper electrode to the lower electrode, the magnetization direction of the storage layer is in the parallel direction with or the opposite direction to the axis of easy magnetization, and thereby information is written in the storage layer.

The lower electrode can be connected to first wiring and the upper electrode can be connected to second wiring. The first wiring and the second wiring may have a single layer structure including Cu, Al, Au, Pt, Ti, or the like, or may have a laminated structure having an ground layer including Cr, Ti, or the like and a Cu layer, an Au layer, a Pt layer, or the like formed thereon. Furthermore, the wiring can have a single layer structure including Ta or the like or a laminated structure including Cu, Ti, and the like. The wiring, the lower electrode (a first electrode), and the upper electrode (with 2) can be formed using, for example, a PVD method exemplified as a sputtering method.

The storage layer has the selection transistor configured by an NMOS-type FET below the laminated structure, a projection image in the direction in which the second wiring (e.g., a bit line) extends can be orthogonal to a projection image in the direction in which a gate electrode (e.g., which also functions as a word line or an address line) included in the NMOS-type FET extends, and the direction in which the second wiring extends can also be parallel with the direction in which the gate electrode included in the NMOS-type FET extends. The selection transistor is connected to the lower electrode via the first wiring.

Although the preferred forms of the element of the present disclosure are as described above and the element has the selection transistor configured by an NMOS-type FET below the laminated structure, a more specific configuration thereof is, for example, not limited, and a configuration of the element including the selection transistor formed on a semiconductor substrate and an interlayer insulating layer covering the selection transistor, in which the first wiring connected to the lower electrode is formed on the interlayer insulating layer, an insulation material layer covering the laminated structure, the interlayer insulating layer, and the first wiring is formed, the second wiring connected to the upper electrode is formed on the insulation material layer, and the first wiring is electrically connected to one source/drain region of the selection transistor via a connection hole (or a connection hole and a landing pad part or lower layer wiring) provided in the interlayer insulating layer can be exemplified. The other source/drain region of the selection transistor is connected to a sense line.

The connection hole electrically connecting the first wiring and the selection transistor can include impurity-doped polysilicon, tungsten, a high melting-point metal such as Ti, Pt, Pd, Cu, TiW, TiNW, WSi₂, or MoSi₂, or a metal silicide, and can be formed using a CVD method or a PVD method that is exemplified as a sputtering method. The wiring can also include these materials. In addition, as materials to form the interlayer insulating layer and the insulation material layer, silicon oxide (SiO₂), silicon nitride (SiN), SiON, SOG, NSG, BPSG, PSG, BSG, LTO, and Al₂O₃ can be exemplified.

As an electronic device (electronic apparatus) of the present disclosure, a portable electronic device such as a mobile apparatus, a game apparatus, a music apparatus, or a video apparatus or a fixed-type electronic device can be exemplified, and a magnetic head can be exemplified. In addition, a memory device (a memory cell unit) including a non-volatile memory element array in which magnetoresistive elements of the present disclosure (specifically memory elements, and more specifically non-volatile memory cells) are arrayed in a two-dimensional matrix shape can be exemplified. That is, a memory cell unit is formed such that a plurality of non-volatile memory cells is arrayed in a two-dimensional matrix shape in a first direction and a second direction that is different from the first direction, and the non-volatile memory cells include magnetoresistive elements of the present disclosure including the various preferred forms, magnetoresistive elements with the first configuration, and magnetoresistive elements with the second configuration.

### Embodiment 1

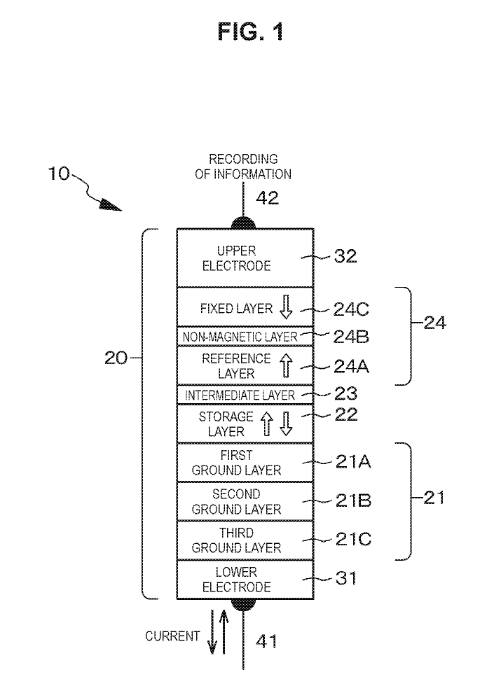

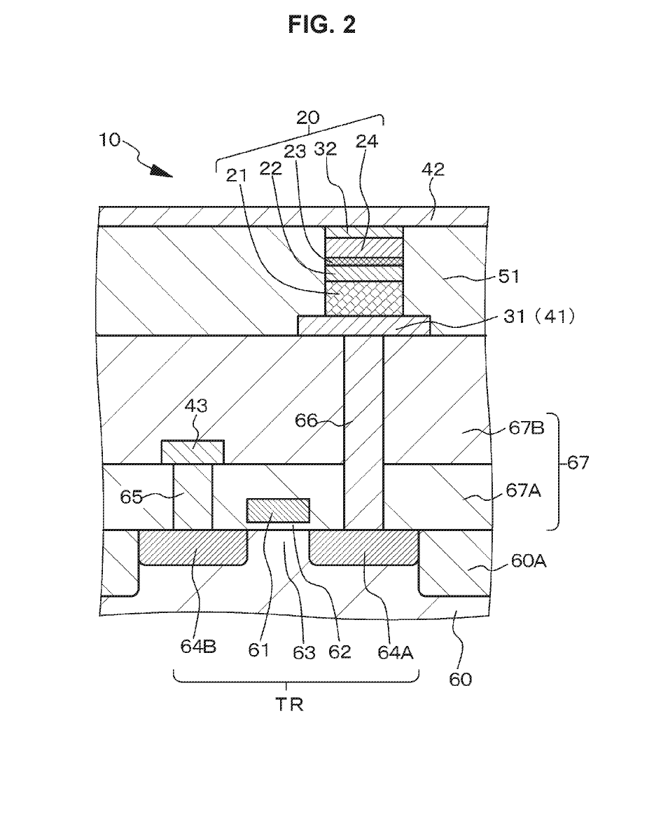

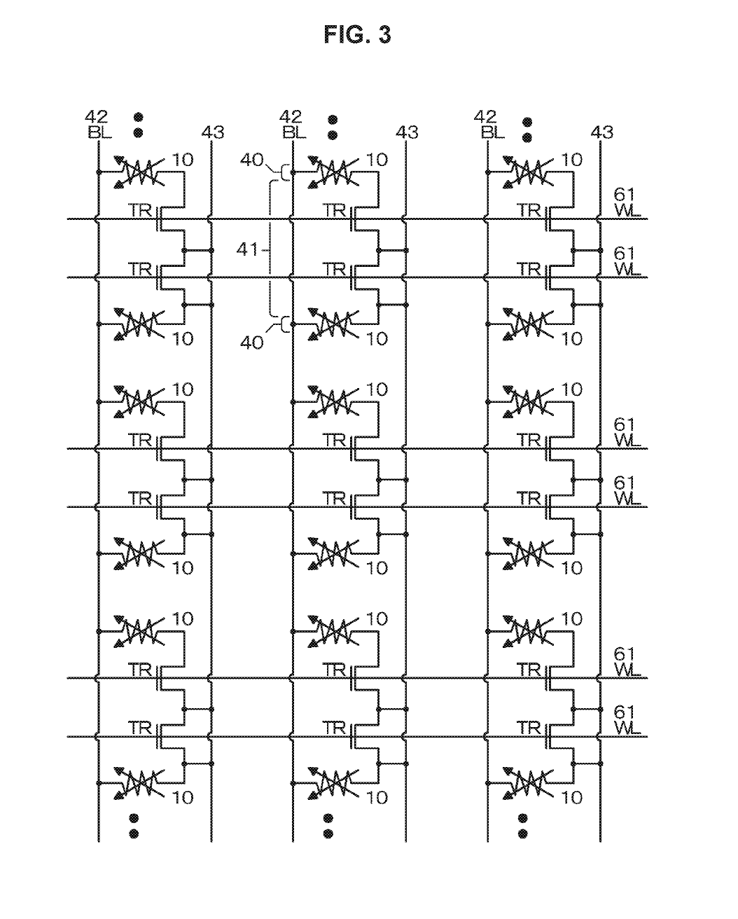

Embodiment 1 relates to a magnetoresistive element of the present disclosure, specifically a magnetoresistive element with the first configuration, and more specifically a magnetoresistive element that is included in, for example, a memory element (a non-volatile memory cell), and to an electronic device of the present disclosure. A conceptual diagram of a magnetoresistive element 10 of Embodiment 1 is illustrated in FIG. 1. In the diagram, magnetization directions are denoted by outlined arrows. In addition, a schematic partial cross-sectional diagram of the magnetoresistive element of Embodiment 1 including a selection transistor is illustrated in FIG. 2, and an equivalent circuit diagram of magnetoresistive elements and a memory cell unit according to Embodiment 1 including selection transistors is illustrated in FIG. 3.

The magnetoresistive element 10 of Embodiment 1 has a top-pin structure in which a lower electrode (first electrode) 31, a first ground layer 21A including a non-magnetic material, a storage layer having perpendicular magnetic anisotropy (which is also called a recording layer, a magnetization reversal layer, or a free layer) 22, an intermediate layer 23, a magnetization fixed layer 24, and an upper electrode (second electrode) 32 are laminated, and the storage layer 22 includes a magnetic material including at least a 3d transition metal element and a boron (B) element in a composition. In addition, a second ground layer 21B is further included between the lower electrode 31 and the first ground layer 21A, and the second ground layer 21B includes a material including at least one kind of element among elements constituting the storage layer 22 in a composition. Here, the second ground layer 21B has in-plane magnetic anisotropy or non-magnetism.

Alternatively, the magnetoresistive element 10 of Embodiment 1 is formed by laminating a lower electrode 31, a first ground layer 21A including a non-magnetic material, a storage layer 22, an intermediate layer 23, a magnetization fixed layer 24, and an upper electrode 32, the storage layer 22 has perpendicular magnetic anisotropy, a second ground layer 21B is further included between the lower electrode 31 and the first ground layer 21A, and the second ground layer 21B has in-plane magnetic anisotropy or non-magnetism.

The electronic device of Embodiment 1 includes a magnetoresistive element 10 or 10A of Embodiment 1 or Embodiment 2, which will be described below. Specifically, the electronic device of Embodiment 1 is a memory device (memory cell unit) including a non-volatile memory element array in which the magnetoresistive elements 10 or 10A of Embodiment 1 or Embodiment 2, which will be described below, are arrayed in a two-dimensional matrix shape. That is, the memory cell unit includes a plurality of non-volatile memory cells arrayed in a first direction and a second direction which is different from the first direction in a two-dimensional matrix shape, and the non-volatile memory cells are constituted by the magnetoresistive elements 10 or 10A of Embodiment 1 or Embodiment 2, which will be described below.

The magnetoresistive element 10 of Embodiment 1 is a magnetoresistive element 10 of a perpendicular magnetization type (spin injection-type magnetoresistance effect element) that performs writing and erasing of information when magnetization of the storage layer 22 is reversed due to spin torque. A magnetization direction of the storage layer 22 changes corresponding to information to be stored, and an axis of easy magnetization of the storage layer 22 is parallel with the laminating direction of a laminated structure 20 constituted by the first ground layer 21A, the storage layer 22, the intermediate layer 23, and the magnetization fixed layer 24. That is, the magnetoresistive element is a perpendicular magnetization type. A magnetization direction of a reference layer 24A is a reference magnetization direction of information to be stored in the storage layer 22, and relative angles formed by a magnetization direction of the storage layer 22 and a magnetization direction of the reference layer 24A define information “0” and information “1.”

In the magnetoresistive element 10 or 10A of Embodiment 1 or Embodiment 2, which will be described below, the storage layer 22 includes specifically a ferromagnetic material having a magnetic moment in which a magnetization direction freely changes in the laminating direction of the laminated structure 20, more specifically a Co—Fe—B alloy [(Co₂₀Fe₈₀)₈₀B₂₀]. Although a three-dimensional shape of the storage layer 22 is set to a tubular shape (cylindrical shape) having a diameter of 60 nm, a shape thereof is not limited thereto. In addition, the boron atom content of the second ground layer 21B is in the range of 10 atomic % to 50 atomic %.

However, although the second ground layer 21B includes a material including at least one kind of element among elements constituting the storage layer 22 in a composition, the second ground layer 21B includes, more specifically, one Co—Fe—B layer [specifically, (Co₂₀Fe₈₀)₈₀B₂₀] in the magnetoresistive element 10 of Embodiment 1. That is, in Embodiment 1, the second ground layer 21B includes the same material as the storage layer 22. In addition, the first ground layer 21A includes one kind of material selected from a group consisting of high melting-point non-magnetic metals such as tantalum, molybdenum, tungsten, titanium, and magnesium, and magnesium oxide [more specifically, tantalum (Ta) in Embodiment 1]. Here, when a thickness of the second ground layer 21B is denoted by T₂ and a thickness of the storage layer 22 is denoted by T₀, T₀≤T₂ is satisfied, and T₂≤3 nm, more specifically, 1 nm≤T₂≤3 nm is satisfied. In addition, when a thickness of the first ground layer 21A is denoted by T₁, 1 nm≤T₁≤4 nm is satisfied. Specific values of T₀, T₁, and T₂ are exemplified in Table 1.

Furthermore, in the magnetoresistive element 10 of Embodiment 1, a third ground layer 21C is formed between the lower electrode 31 and the second ground layer 21B. Here, the third ground layer 21C includes one kind of material selected from a group consisting of high melting-point non-magnetic metals such as tantalum, molybdenum, tungsten, titanium, and magnesium, and magnesium oxide, specifically, tantalum (Ta) in Embodiment 1. That is, the third ground layer 21C includes the same material as the material that forms the first ground layer 21A. Note that the first ground layer 21A, the second ground layer 21B, and the third ground layer 21C are collectively denoted by a ground layer 21 in FIG. 2.

The magnetization fixed layer 24 has a laminated ferromagnetic structure in which at least two magnetic material layers are laminated. A non-magnetic layer 24B is formed between one magnetic material layer (reference layer) 24A constituting the laminated ferromagnetic structure and the other magnetic material layer (fixed layer) 24C constituting the laminated ferromagnetic structure. An axis of easy magnetization of the reference layer 24A is parallel with the laminating direction of the laminated structure 20. That is, the reference layer 24A includes a ferromagnetic material having a magnetic moment in which a magnetization direction changes in a direction parallel with the laminating direction of the laminated structure 20, and more specifically, including a Co—Fe—B alloy [(Co₂₀Fe₈₀)₈₀B₂₀]. Furthermore, the fixed layer 24C includes a Co—Pt alloy layer and has a laminated ferromagnetic structure in which the fixed layer is magnetically coupled with the reference layer 24A via the non-magnetic layer 24B that includes ruthenium (Ru).

The intermediate layer 23 that includes a non-magnetic material includes an insulating layer that functions as a tunnel barrier layer (tunnel insulating layer), specifically, a magnesium oxide (MgO) layer. By forming the intermediate layer 23 as an MgO layer, a magnetoresistance change ratio (MR ratio) can be increased, the effect of spin injection can be improved accordingly, and a density of a magnetization reversal current necessary for reversing a magnetization direction of the storage layer 22 can be reduced.

The lower electrode 31 is connected to first wiring 41, and the upper electrode 32 is connected to second wiring 42. In addition, information is stored in the storage layer 22 by causing a current (magnetization reversal current) to flow between the first wiring 41 and the second wiring 42. That is, a magnetization direction of the storage layer 22 is changed when a magnetization reversal current flows in the laminating direction of the laminated structure 20, and thereby information is recorded in the storage layer 22.

The above-described layer configurations of the laminated structure 20 are exemplified together in the following table 1.

```
TABLE 1
    Upper electrode 32: Ru layer (upper layer) having a thickness of
3 nm/Ta layer (lower layer) having a thickness of 5 nm
    Magnetization fixed layer 24
        Fixed layer 24C: Co—Pt alloy layer having a film thickness
        of 2.5 nm
        Non-magnetic layer 24B: Ru layer having a film thickness
        of 0.8 nm
        Reference layer 24A: (Co₂₀Fe₈₀)₈₀B₂₀ layer having
        a film thickness of 1.0 nm
        Intermediate layer 23: MgO layer having a film thickness
        of 1.0 nm
        Storage layer 22: (Co₂₀Fe₈₀)₈₀B₂₀ layer having a film
        thickness (T₀) of 1.25 nm
    Ground layers
        First ground layer 21A: Ta layer having a film thickness (T₁)
        of 1.0 nm
        Second ground layer 21B: (Co₂₀Fe₈₀)₈₀B₂₀ layer having
a film thickness (T₂) of 2.0 nm
        Third ground layer 21C: Ta layer (a thickness of 5 nm)
    Lower electrode 31: TaN layer (a thickness of 5 nm)
```

A selection transistor TR configured by an NMOS-type FET is provided below the laminated structure 20. Specifically, the selection transistor TR formed on a semiconductor substrate 60 and an interlayer insulating layer 67 (67A and 67B) that covers the selection transistor TR are provided, the first wiring 41 (that also serves as the lower electrode 31) is formed on the interlayer insulating layer 67, the laminated structure 20 is formed on the first wiring 41, the insulation material layer 51 is formed on the interlayer insulating layer 67, surrounding the laminated structure 20, and the second wiring 42 connected to the upper electrode 32 is formed on the insulation material layer 51.

In addition, the first wiring 41 (the lower electrode 31) is electrically connected to one source/drain region (drain region) 64A of the selection transistor TR via a connection hole (or a connection hole and a landing pad part or lower layer wiring) 66 provided in the interlayer insulating layer 67.

The selection transistor TR includes a gate electrode 61, a gate insulating layer 62, a channel formation region 63, and source/drain regions 64A and 64B. The one source/drain region (drain region) 64A and the first wiring 41 are connected via the connection hole 66 as described above. The other source/drain region (source region) 64B is connected to a sense line 43 via a connection hole 66. The gate electrode 61 functions as a so-called word line WL or an address line. In addition, a projection image in the direction in which the second wiring 42 (a bit line BL) extends is orthogonal to a projection image in the direction in which the gate electrode 61 extends or is parallel with a projection image in the direction in which the second wiring 42 extends.

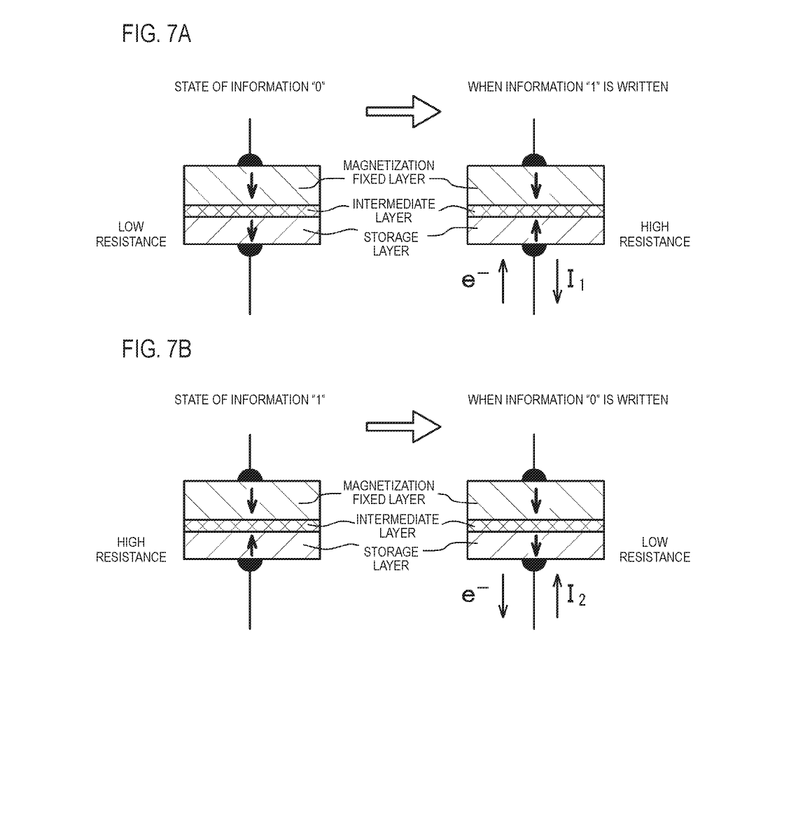

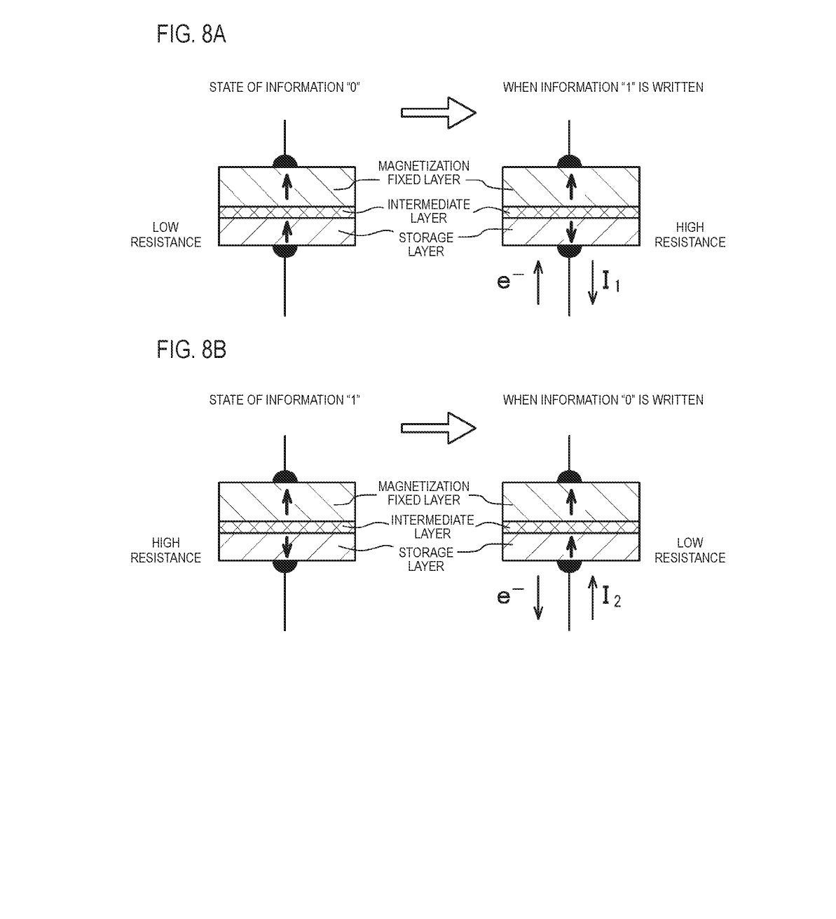

It is assumed that information “0” stored in the storage layer 22 is to be rewritten to “1” as illustrated in the conceptual diagrams of FIG. 7A and FIG. 8A. That is, a write current (magnetization reversal current) I₁ flows from the magnetization fixed layer 24 to the selection transistor TR via the storage layer 22 in a parallel magnetization state. In other words, electrons flow from the storage layer 22 to the magnetization fixed layer 24. Specifically, for example, V_{dd} is applied to the second wiring 42, and the source region 64B of the selection transistor TR is grounded. Electrons having a spin in one direction that have reached the magnetization fixed layer 24 pass through the magnetization fixed layer 24. On the other hand, electrons having a spin in another direction are reflected by the magnetization fixed layer 24. In addition, when the electrons enter the storage layer 22, torque is imposed on the storage layer 22, and thus the state of the storage layer 22 is reversed to an anti-parallel magnetization state. Here, it may be thought that the magnetization direction of the magnetization fixed layer 24 is fixed and thus is not reversed and the state of the storage layer 22 is reversed to keep angular momentum of the whole system.

It is assumed that information “1” stored in the storage layer 22 is to be rewritten to “0” as illustrated in the conceptual diagrams of FIG. 7B and FIG. 8B. That is, a write current I₂ flows from the selection transistor TR to the magnetization fixed layer 24 via the storage layer 22 in an anti-parallel magnetization state. In other words, electrons flow from the magnetization fixed layer 24 to the storage layer 22. Specifically, for example, V_{dd} is applied to the source region 64B of the selection transistor TR, and the second wiring 42 is grounded. The electrons that have passed through the magnetization fixed layer 24 are subject to spin polarization, that is, a difference is made between the numbers of upward and downward electrons. When a thickness of the intermediate layer 23 is sufficiently thin and electrons reach the storage layer 22 before the spin polarization relaxes and thus the layer returns to a non-polarization state (a state in which upward and downward electrons are the same in number) of a normal non-magnetic body, the sign at the time of spin polarization is reversed, and thus some electrons are reversed, that is, change the direction of spin angular momentum to lower the energy of the whole system. At this time, since the entire angular momentum of the system should be kept, a reaction whose amount is equivalent to the sum of a change in the angular momentum by the direction-changed electrons is given to the magnetic moment of the storage layer 22. In a case in which a current, that is, the number of electrons passing through the magnetization fixed layer 24 in unit time is small, the total number of direction-changed electrons is small, thus the quantity of change of the angular momentum that occurs in the magnetic moment of the storage layer 22 is small accordingly, but if the current increases, a greater change of the angular momentum can be given to the storage layer 22 within unit time. The temporal change of the angular momentum is torque, and when the torque exceeds a certain threshold value, the magnetic moment of the storage layer 22 starts reversing and rotates 180 degrees due to uniaxial anisotropy of the layer, and at last the layer is stabilized. That is, the reversal from the anti-parallel magnetization state to the parallel magnetization state occurs, and thereby information “0” is recorded in the storage layer 22.

When information written in the storage layer 22 is to be read, the selection transistor TR of the magnetoresistive element 10 from which information is to be read is in a conductive state. In addition, a current flows between the second wiring 42 (bit line BL) and the sense line 43, and a potential appearing in the bit line BL is input to one input unit of a comparator circuit (not illustrated) constituting a comparison circuit (not illustrated). Meanwhile, a potential from a circuit (not illustrated) for obtaining a reference resistance value is input to the other input unit of the comparator circuit constituting the comparison circuit. Then, the comparison circuit compares whether the potential appearing in the bit line BL is high or low with reference to the potential from the circuit for obtaining the reference resistance value, and the comparison result (information 0 or 1) is output from the output unit of the comparator circuit constituting the comparison circuit.

An overview of a manufacturing method of the magnetoresistive element of Embodiment 1 will be described below.

### [Step-100]

First, an element isolation region 60A is formed on the semiconductor substrate 60 including a silicon semiconductor substrate using a known method, and the selection transistor TR including the gate insulating layer 62, the gate electrode 61, the source/drain regions 64A and 64B is formed in a part of the semiconductor substrate 60 surrounded by the element isolation region 60A. The part of the semiconductor substrate 60 located between the source/drain region 64A and the source/drain region 64B corresponds to the channel formation region 63. Next, a lower layer 67A of the interlayer insulating layer 67 is formed, a connection hole (tungsten plug) 65 is formed in a part of the lower layer 67A on the one source/drain region (source region) 64B, and further the sense line 43 is formed on the lower layer 67A. Then, an upper layer 67B of the interlayer insulating layer 67 is formed on the entire surface of the lower layer. In addition, the connection hole (tungsten plug) 66 is formed in parts of the upper layer 67B and the lower layer 67A on the other source/drain region (drain region) 64A. In this way, the selection transistor TR covered by the interlayer insulating layer 67 can be obtained. In addition, after a conductive material layer for forming the first wiring 41 which also serves as the lower electrode 31 is formed on the interlayer insulating layer 67, the conductive material layer is patterned, and thereby the first wiring 41 that also serves as the lower electrode 31 can be obtained. The first wiring 41 is in contact with the connection hole 66.

### [Step-110]

Then, the third ground layer 21C, the second ground layer 21B, the first ground layer 21A, the storage layer 22, the intermediate layer 23, the reference layer 24A, the non-magnetic layer 24B, the fixed layer 24C, and the upper electrode 32 are sequentially formed on the entire surface of the lower electrode, the formed films are patterned, and thereby the laminated structure 20 can be obtained. Note that, the intermediate layer 23 including magnesium oxide (MgO) is formed by performing film formation of an MgO layer using an RF magnetron sputtering method. In addition, the other layers are formed using a DC magnetron sputtering method.

### [Step-120]

Next, the insulation material layer 51 is formed on the entire surface of the lower electrode. Then, a flattening process is performed on the insulation material layer 51 to level the top surface of the insulation material layer 51 with that of the upper electrode 32. Thereafter, the second wiring 42 that is in contact with the upper electrode 32 is formed on the insulation material layer 51. In this way, the magnetoresistive element 10 with the structure illustrated in FIG. 2 (specifically, a spin injection-type magnetoresistance effect element) can be obtained. Note that patterning of each layer can be performed using an RIE method or an ion milling method (ion beam etching method).

As described above, the general MOS manufacturing process can be applied to manufacturing of the magnetoresistive element of Embodiment 1, and it can be applied as a universal memory.

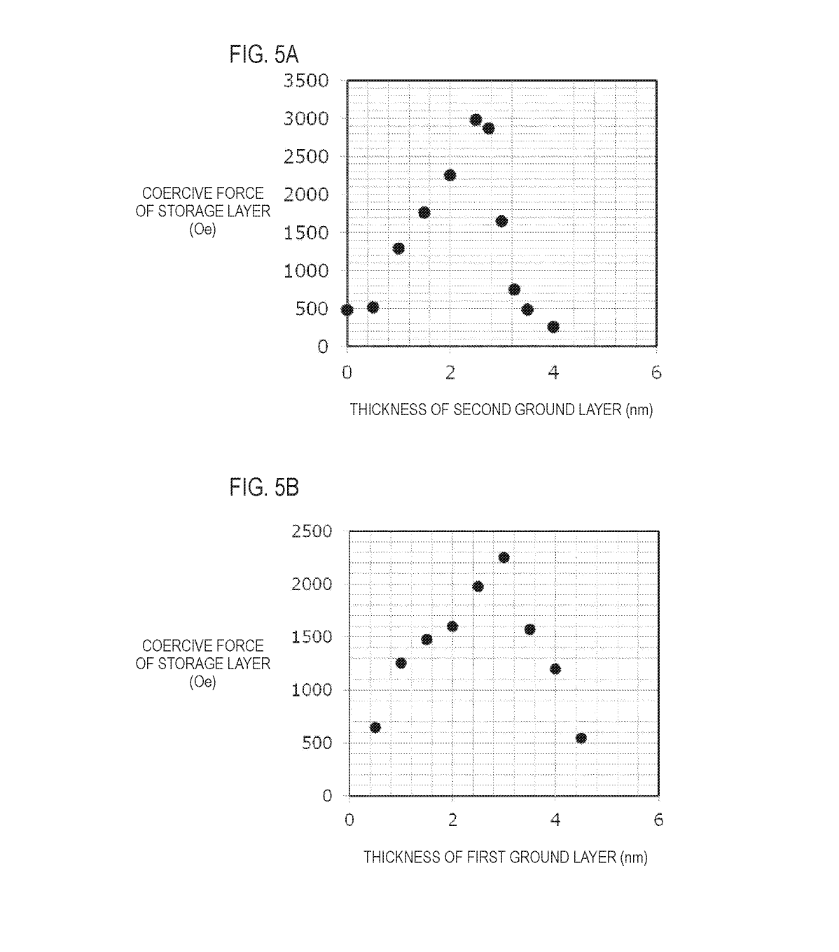

How retention power of the storage layer 22 (unit: Oe) changes when the thickness of the second ground layer 21B (T₂) is changed in the configuration shown in Table 1 was examined. The result is shown in FIG. 5A. Note that a magnetic field from outside was applied to the magnetoresistive element after it was manufactured, an electrical resistance value of the manufactured magnetoresistive element was measured, and thereby coercive force of the storage layer 22 was calculated from a value of the magnetic field when the electrical resistance value was radically changed. The same applied to the following description as well.

In addition, FIG. 5A illustrates data of the magnetoresistive element with T₂=0 (i.e., the magnetoresistive element in which the second ground layer 21B is not formed) as Comparative Example 1A. In Comparative Example 1A, the ground layer includes one tantalum layer.

It is ascertained from FIG. 5A that, by setting the thickness of the second ground layer 21B (T₂) to be 1 nm≤T₂≤3 nm, the coercive force of the storage layer 22 further increases and perpendicular magnetic anisotropy is further strengthened than the magnetoresistive element of Comparative Example 1A.

In addition, how retention power of the storage layer 22 (unit: Oe) changes when the thickness of the first ground layer 21A (T₁) is changed in the configuration shown in Table 1 was examined. The result is shown in FIG. 5B, and it is ascertained that satisfying 1 nm≤T₁≤4 nm is preferable.

A prototype of the magnetoresistive element for Comparative Example 1B was made in which a second ground layer formed by laminating a Pt layer, a Co layer, a Pt layer, and a Co layer and a first ground layer (having a film thickness of 0.4 nm) including Ta are formed on a third ground layer including Ta and a storage layer, an intermediate layer, and a magnetization fixed layer, which are similar to those of Embodiment 1, are formed on the first ground layer.

Write current values (unit: micro ampere), thermal stability, and thermal disturbance constants, which are an index of data retention (unit: dimensionless), of the magnetoresistive elements of Embodiment 1, Embodiment 2, which will be described below, Comparative Example 1A, and Comparative Example 1B were measured. The results are shown in Table 2.

TABLE 2

| | Write | Thermal |
|---|---|---|
| | current value | disturbance constant |
| Embodiment 1 | 70 | 86 |
| Embodiment 2 | 65 | 80 |
| Comparative Example 1A | 20 | 51 |
| Comparative Example 1B | 275 | 94 |

The coercive force of the magnetoresistive element of Comparative Example 1B was about 4370 (Oe), which is higher than that of the magnetoresistive element of Embodiment 1. That is, since the second ground layer formed by laminating a Pt layer, a Co layer, a Pt layer, and a Co layer is provided and the thin first ground layer having a thickness of 0.4 nm is provided in Comparative Example 1B, it is thought that the second ground layer is magnetically coupled with the storage layer via the thin first ground layer and the storage layer 22 exhibits greater perpendicular magnetic anisotropy than that of Embodiment 1. However, as shown in Table 2, the magnetoresistive element of Comparative Example 1B exhibited much higher write current value than that of Embodiment 1.

In addition, although the magnetoresistive elements of Embodiment 1 and Comparative Example 1B exhibited thermal disturbance constants of a similar degree as shown in Table 2, the magnetoresistive element of Comparative Example 1A exhibited a much lower thermal disturbance constant. That is, it is ascertained that thermal stability of a magnetoresistive element becomes low when the second ground layer is not provided.

As described above, in the magnetoresistive element of Embodiment 1, the second ground layer provided between the lower electrode and the first ground layer includes a material including at least one kind of element among elements constituting the storage layer in a composition, or has in-plane magnetic anisotropy or non-magnetism. In addition, by providing the second ground layer formed as described above, a crystal orientation of the first ground layer is improved, as a result, perpendicular magnetic anisotropy of the storage layer formed on the first ground layer can be improved, and thus coercive force of the storage layer can be increased. Moreover, the problem of a high write current value can be avoided. Furthermore, the magnetoresistive element of Embodiment 1 has high thermal stability.

In addition, the ground layers have simple structures and can be easily manufactured, and the storage layer can exhibit high perpendicular magnetic anisotropy and coercive force even if the storage layer is set to have a single layer configuration. Furthermore, the first ground layer can reliably prevent at least one kind of element (specifically, boron) of the elements constituting the storage layer from diffusing into the material forming the second ground layer.

### Embodiment 2

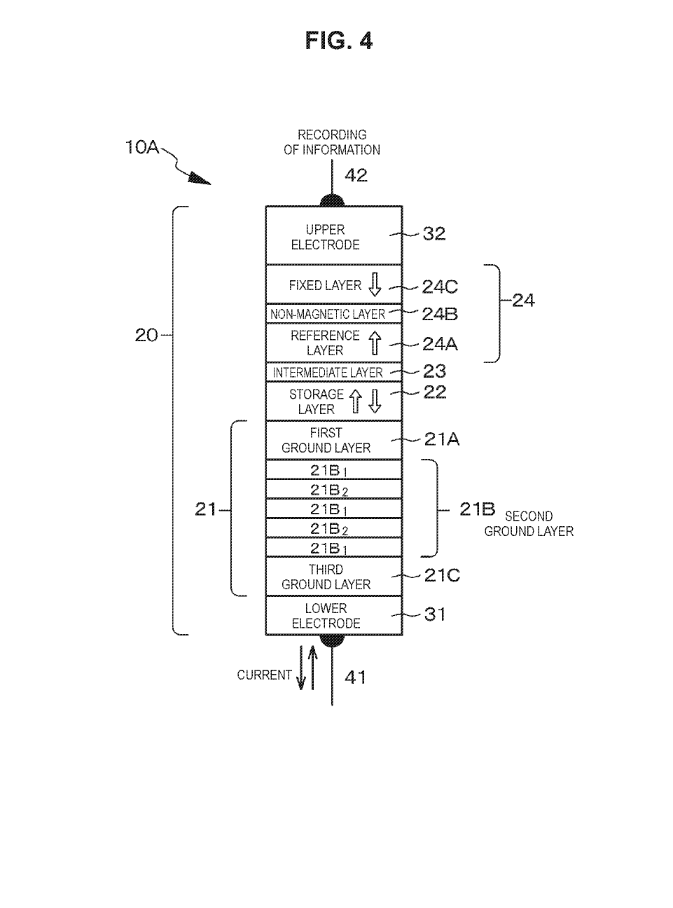

Embodiment 2 is a modification of Embodiment 1 and relates to a magnetoresistive element with the second configuration. A conceptual diagram of the magnetoresistive element 10A of Embodiment 2 is illustrated in FIG. 4. In Embodiment 2, a second ground layer 21B is formed by alternately laminating first material layers 21B₁ and second material layer 21B₂. The first material layer 21B₁ includes a Co—Fe—B layer [specifically, a (Co₂₀Fe₈₀)₈₀B₂₀ layer]. That is, in Embodiment 2, the first material layer 21B₁ includes the same material as the storage layer 22. In addition, the second material layer 21B₂ includes a non-magnetic material layer. The second material layer 21B₂ includes one kind of material selected from a group consisting of a high melting-point non-magnetic metal such as tantalum, molybdenum, tungsten, titanium, and magnesium, and magnesium oxide, specifically, is made of tantalum (Ta) in Embodiment 2. In addition, a material included in the first ground layer 21A and a material included in the second material layer 21B₂ are the same (specifically, tantalum). Furthermore, when a thickness of the second ground layer 21B is denoted by T₂′, 3 nm≤T₂′ is satisfied. Although the measurement results of a write current value and a thermal disturbance constant when T₂′=4 nm are shown in Table 2, they have substantially the same values as those of the magnetoresistive element of Embodiment 1. In addition, the coercive force of the magnetoresistive element of Embodiment 2 is about 2800 (Oe), which is a value of the same degree as that of Embodiment 1.

Since the configuration and the structure of the magnetoresistive element of Embodiment 2 are similar to the configuration and the structure of that of Embodiment 1 except the above-described points, detailed description thereof will be omitted.

### Embodiment 3

Embodiment 3 relates to an electronic device having the magnetoresistive element 10 or 10A described in Embodiment 1 or Embodiment 2, specifically, a magnetic head. Magnetic heads can be applied to various electronic apparatuses, electric apparatuses, and the like beginning from, for example, hard disk drives, integrated circuit chips, personal computers, mobile terminals, mobile telephones, and magnetic sensor apparatuses.

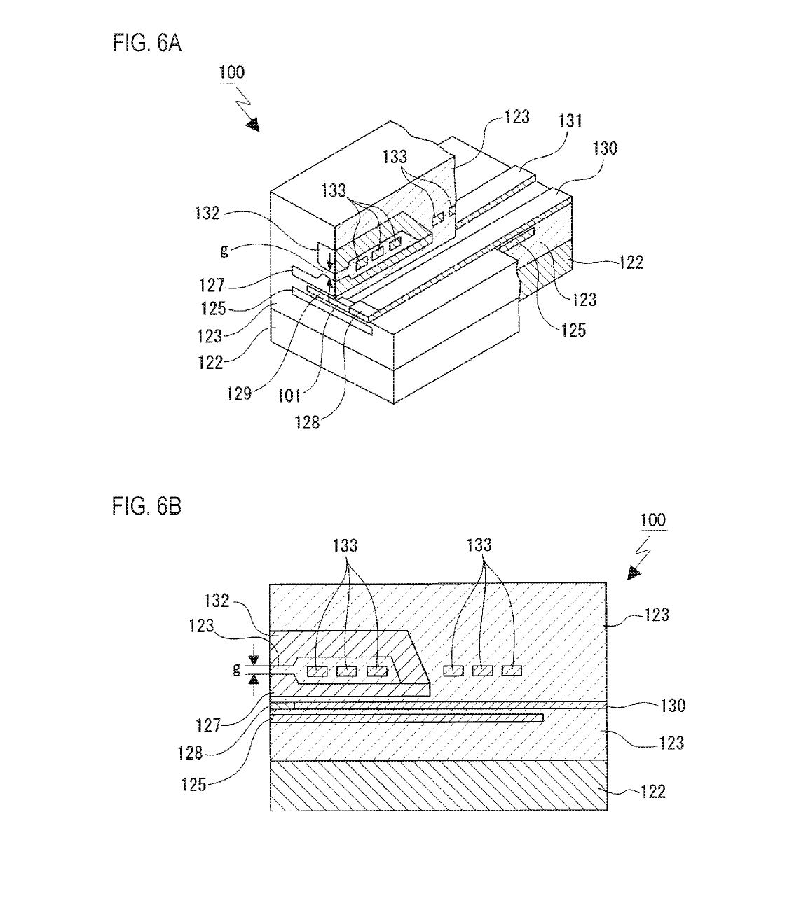

As an example, FIG. 6A and FIG. 6B illustrate an example in which a magnetoresistive element 101 is applied to a composite magnetic head 100. Note that FIG. 6A is a schematic perspective diagram illustrating the composite magnetic head 100 of which a part has been cut to see the internal structure and FIG. 6B is a schematic cross-sectional diagram of the composite magnetic head 100.

The composite magnetic head 100 is a magnetic head that is used in a hard disk device or the like, a magnetoresistance effect magnetic head with the magnetoresistive element 10 or 10A described in Embodiment 1 or Embodiment 2 is formed on a substrate 122, and an inductive magnetic head is further laminated and formed on the magnetoresistance effect magnetic head. Here, the magnetoresistance effect magnetic head operates as a head for reproduction, and the inductive magnetic head operates a head for recording. That is, a head for reproduction and a head for recording are combined in the composite magnetic head 100.

The magnetoresistance effect magnetic head mounted in the composite magnetic head 100 is a so-called shield MR head, and includes a first magnetic shield layer 125 formed on the substrate 122 via an insulating layer 123, a magnetoresistive element 101 formed on the first magnetic shield layer 125 via the insulating layer 123, and a second magnetic shield layer 127 formed on the magnetoresistive element 101 via the insulating layer 123. The insulating layer 123 includes an insulating material such as Al₂O₃ or SiO₂. The first magnetic shield layer 125 is a layer magnetically shielding the ground layer side of the magnetoresistive element 101, and includes a soft magnetic material such as Ni—Fe. The magnetoresistive element 101 is formed on the first magnetic shield layer 125 via the insulating layer 123. The magnetoresistive element 101 functions as a magneto-sensitive element that detects magnetic signals from a magnetic recording medium in the magnetoresistance effect magnetic head. A shape of the magnetoresistive element 101 is a substantially rectangular shape, and one side surface thereof is exposed as a surface facing a magnetic recording medium. In addition, bias layers 128 and 129 are disposed at both ends of the magnetoresistive element 101. In addition, connection terminals 130 and 131 that are connected to the bias layers 128 and 129 are formed. A sense current is supplied to the magnetoresistive element 101 via the connection terminals 130 and 131. The second magnetic shield layer 127 is provided above the bias layers 128 and 129 via the insulating layer 123.

The inductive magnetic head laminated and formed on the magnetoresistance effect magnetic head includes a magnetic core including the second magnetic shield layer 127 and an upper layer core 132, and thin film coils 133 formed to wind the magnetic core. The upper layer core 132 forms a closed magnetic path together with the second magnetic shield layer 127, serves as a magnetic core of the inductive magnetic head, and includes a soft magnetic material such as Ni—Fe. Here, the second magnetic shield layer 127 and the upper layer core 132 are formed such that the front end parts thereof are exposed as surfaces facing the magnetic recording medium and the second magnetic shield layer 127 and the upper layer core 132 are in contact with each other at the rear end parts. Here, the front end parts of the second magnetic shield layer 127 and the upper layer core 132 are formed such that the second magnetic shield layer 127 and the upper layer core 132 are separated having a predetermined gap g with respect to the surface facing the magnetic recording medium. That is, in the composite magnetic head 100, the second magnetic shield layer 127 magnetically shields the upper layer side of the magnetoresistive element 101 and also serves as a magnetic core of the inductive magnetic head, and the second magnetic shield layer 127 and the upper layer core 132 constitute the magnetic core of the inductive magnetic head. In addition, the gap g is a magnetic gap for recording of the inductive magnetic head.

In addition, the thin film coils 133 embedded in the insulating layer 123 are formed above the second magnetic shield layer 127. The thin film coils 133 are formed to wind the magnetic coil including the second magnetic shield layer 127 and the upper layer core 132. Although not illustrated, both end parts of the thin film coils 133 are exposed to outside, and terminals formed at both ends of the thin film coils 133 are external connection terminals of the inductive magnetic head. That is, when a magnetic signal is recorded into the magnetic recording medium, recording currents are supplied from the external connection terminals to the thin film coils 133.

Although the composite magnetic head 100 described above has the magnetoresistance effect magnetic head mounted as a head for reproduction, the magnetoresistance effect magnetic head includes the magnetoresistive element 101 described in Embodiment 1 or Embodiment 2 as a magneto-sensitive element that detects magnetic signals from the magnetic recording medium. In addition, since the magnetoresistive element 101 exhibits very excellent characteristics as described above, the magnetoresistance effect magnetic head can achieve a higher recording density of magnetic recording.

Although the present disclosure has been described above on the basis of embodiments, the present disclosure is not limited to the embodiments. Various laminated structures, used materials, and the like described in the embodiments are merely examples, and can be appropriately modified.

Additionally, the present technology may also be configured as below.

### [A01]<<Magnetoresistive Element: First Aspect>>

A magnetoresistive element formed by laminating a lower electrode, a first ground layer including a non-magnetic material, a storage layer having perpendicular magnetic anisotropy, an intermediate layer, a magnetization fixed layer, and an upper electrode,

in which the storage layer includes a magnetic material including at least a 3d transition metal element and a boron element in a composition,

a second ground layer is further included between the lower electrode and the first ground layer, and

the second ground layer includes a material including at least one kind of element among elements constituting the storage layer in a composition.

### [A02]

The magnetoresistive element according to [A01], in which the second ground layer has in-plane magnetic anisotropy or non-magnetism.

### [A03]

The magnetoresistive element according to [A01] or [A02],

in which the storage layer includes Co—Fe—B, and

a boron atom content of the second ground layer is in a range of 10 atomic % to 50 atomic %.

[A04]<<Magnetoresistive Element with First Configuration>>

The magnetoresistive element according to any one of [A01] to [A03],

in which the second ground layer includes one Co—Fe—B layer, and

the first ground layer includes one kind of material selected from a group consisting of tantalum, molybdenum, tungsten, titanium, magnesium, and magnesium oxide.

### [A05]

The magnetoresistive element according to [A04], in which, when a thickness of the second ground layer is denoted by T₂ and a thickness of the storage layer is denoted by T₀, T₀≤T₂ is satisfied.

### [A06]

The magnetoresistive element according to [A05], in which T₂≤3 nm is satisfied.

[A07] The magnetoresistive element described in any one of [A04] to [A06] in which a third ground layer is formed between a lower electrode and the second ground layer.

### [A08]

The magnetoresistive element according to [A07], in which the third ground layer includes one kind of material selected from a group consisting of tantalum, molybdenum, tungsten, titanium, magnesium, and magnesium oxide.

### [A09]

The magnetoresistive element according to [A07], in which the third ground layer includes a same material as a material included in the first ground layer.

[A10]<<Magnetoresistive Element with Second Configuration>>

The magnetoresistive element according to any one of [A01] to [A03], in which the second ground layer is formed by alternately laminating a first material layer and a second material layer.

### [A11]

The magnetoresistive element according to [A10],

in which the first material layer includes a Co—Fe—B layer, and

the second material layer includes a non-magnetic material layer.

### [A12]

The magnetoresistive element according to [A10] or [A11], in which the second material layer includes one kind of material selected from a group consisting of tantalum, molybdenum, tungsten, titanium, magnesium, and magnesium oxide.

### [A13]

The magnetoresistive element according to any one of [A10] to [A12], in which a material included in the first ground layer and a material included in the second material layer are same materials.

### [A14]

The magnetoresistive element according to any one of [A10] to [A13], in which, when a thickness of the second ground layer is denoted by T₂′, 3 nm T₂′ is satisfied.

[A15] The magnetoresistive element described in any one of [A10] to [A14] in which, when a thickness of the first material layer is denoted by T_{2-A}′ and a thickness of the second material layer is denoted by T_{2-B}′, 0.2≤T_{2-A}′/T_{2-B}′≤5 is satisfied.
[A16] The magnetoresistive element described in any one of [A10] to [A15] in which when a thickness of the first material layer is denoted by T_{2-A}′ and a thickness of the storage layer is denoted by T₀, T_{2-A}′<T₀ is satisfied.

### [A15]

The magnetoresistive element according to any one of [A01] to [A14], in which, when a thickness of the first ground layer is denoted by T₁, 1 nm≤T₁≤4 nm is satisfied.

### [B01]<<Magnetoresistive Element: Second Aspect>>

A magnetoresistive element formed by laminating a lower electrode, a first ground layer including a non-magnetic material, a storage layer, an intermediate layer, a magnetization fixed layer, and an upper electrode,

in which the storage layer has perpendicular magnetic anisotropy,

a second ground layer is further included between the lower electrode and the first ground layer, and

the second ground layer has in-plane magnetic anisotropy or non-magnetism.

### [B02]

The magnetoresistive element according to [B01],

in which the storage layer includes Co—Fe—B, and

a boron atom content of the second ground layer is in a range of 10 atomic % to 50 atomic %.

[B03]<<Magnetoresistive Element with First Configuration>>

The magnetoresistive element according to [B01] or [B02],

in which the second ground layer includes one Co—Fe—B layer, and

the first ground layer includes one kind of material selected from a group consisting of tantalum, molybdenum, tungsten, titanium, magnesium, and magnesium oxide.

### [B04]

The magnetoresistive element according to [B03], in which, when a thickness of the second ground layer is denoted by T₂ and a thickness of the storage layer is denoted by T₀, T₀≤T₂ is satisfied.

[B05] The magnetoresistive element described in [B04] in which T₂≤3 nm is satisfied.
[B06] The magnetoresistive element described in any one of [B03] to [B05] in which a third ground layer is formed between a lower electrode and the second ground layer.

### [B07]

The magnetoresistive element according to [B06], in which the third ground layer includes one kind of material selected from a group consisting of tantalum, molybdenum, tungsten, titanium, magnesium, and magnesium oxide.

### [B08]

The magnetoresistive element according to [B06], in which the third ground layer includes a same material as a material included in the first ground layer.

[B09]<<Magnetoresistive Element with Second Configuration>>

The magnetoresistive element according to [B01] or [B02], in which the second ground layer is formed by alternately laminating a first material layer and a second material layer.

### [B10]

The magnetoresistive element according to [B09],

in which the first material layer includes a Co—Fe—B layer, and

the second material layer includes a non-magnetic material layer.

### [B11]

The magnetoresistive element according to [B09] or [B10], in which the second material layer includes one kind of material selected from a group consisting of tantalum, molybdenum, tungsten, titanium, magnesium, and magnesium oxide.

### [B12]

The magnetoresistive element according to any one of [B09] to [B11], in which a material included in the first ground layer and a material included in the second material layer are same materials.

### [B13]

The magnetoresistive element according to any one of [B09] to [B12], in which, when a thickness of the second ground layer is denoted by T₂′, 3 nm≤T₂′ is satisfied.

### [B14]

The magnetoresistive element according to any one of [B01] to [B13], in which, when a thickness of the first ground layer is denoted by T₁, 1 nm≤T₁≤4 nm is satisfied.

### [C01]<<Electronic Device>>

An electronic device including:

the magnetoresistive element according to any one of [A01 to [B14].

### [C02]<Memory Cell Unit>

A memory cell unit in which a plurality of non-volatile memory cells is arrayed in a first direction and a second direction that is different from the first direction in a two-dimensional matrix shape, and the non-volatile memory cells include the magnetoresistive element described in any one of [A01 to [B14].

### REFERENCE SIGNS LIST

10, 10A magnetoresistive element
20 laminated structure
21 ground layer
21A first ground layer
21B second ground layer
21C third ground layer
22 storage layer
23 intermediate layer
24 magnetization fixed layer
24A reference layer
24B non-magnetic layer
24C fixed layer
31 lower electrode (first electrode)
32 upper electrode (second electrode)
41 first wiring
42 second wiring
43 sense line
51 insulation material layer
TR selection transistor
60 semiconductor substrate
60A element isolation region
61 gate electrode
62 gate insulating layer
63 channel formation region
64A, 64B source/drain region
65 tungsten plug
66 connection hole
67, 67A, 67B interlayer insulating layer
100 composite magnetic head
101 magnetoresistive element
122 substrate
123 insulating layer
125 first magnetic shield layer
127 second magnetic shield layer
128, 129 bias layer
130, 131 connection terminal
132 upper layer core
133 thin film coil

1. A magnetoresistive element formed by laminating a lower electrode, a first ground layer including a non-magnetic material, a storage layer having perpendicular magnetic anisotropy, an intermediate layer, a magnetization fixed layer, and an upper electrode,
wherein the storage layer includes a magnetic material including at least a 3d transition metal element and a boron element in a composition,
a second ground layer is further included between the lower electrode and the first ground layer, and
the second ground layer includes a material including at least one kind of element among elements constituting the storage layer in a composition.

2. The magnetoresistive element according to claim 1, wherein the second ground layer has in-plane magnetic anisotropy or non-magnetism.

3. The magnetoresistive element according to claim 1,
wherein the storage layer includes Co—Fe—B, and
a boron atom content of the second ground layer is in a range of 10 atomic % to 50 atomic %.

4. The magnetoresistive element according to claim 1,
wherein the second ground layer includes one Co—Fe—B layer, and
the first ground layer includes one kind of material selected from a group consisting of tantalum, molybdenum, tungsten, titanium, magnesium, and magnesium oxide.

5. The magnetoresistive element according to claim 4, wherein, when a thickness of the second ground layer is denoted by T₂ and a thickness of the storage layer is denoted by T₀, T₀≤T₂ is satisfied.

6. The magnetoresistive element according to claim 5, wherein T₂≤3 nm is satisfied.

7. The magnetoresistive element according to claim 4, wherein a third ground layer is formed between the lower electrode and the second ground layer.

8. The magnetoresistive element according to claim 7, wherein the third ground layer includes one kind of material selected from a group consisting of tantalum, molybdenum, tungsten, titanium, magnesium, and magnesium oxide.

9. The magnetoresistive element according to claim 7, wherein the third ground layer includes a same material as a material included in the first ground layer.

10. The magnetoresistive element according to claim 1, wherein the second ground layer is formed by alternately laminating a first material layer and a second material layer.

11. The magnetoresistive element according to claim 10,
wherein the first material layer includes a Co—Fe—B layer, and
the second material layer includes a non-magnetic material layer.

12. The magnetoresistive element according to claim 10, wherein the second material layer includes one kind of material selected from a group consisting of tantalum, molybdenum, tungsten, titanium, magnesium, and magnesium oxide.

13. The magnetoresistive element according to claim 10, wherein a material included in the first ground layer and a material included in the second material layer are same materials.

14. The magnetoresistive element according to claim 10, wherein, when a thickness of the second ground layer is denoted by T₂′, 3 nm≤T₂′ is satisfied.

15. The magnetoresistive element according to claim 1, wherein, when a thickness of the first ground layer is denoted by T₁, 1 nm≤T₁≤4 nm is satisfied.

16. A magnetoresistive element formed by laminating a lower electrode, a first ground layer including a non-magnetic material, a storage layer, an intermediate layer, a magnetization fixed layer, and an upper electrode,
wherein the storage layer has perpendicular magnetic anisotropy,
a second ground layer is further included between the lower electrode and the first ground layer, and
the second ground layer has in-plane magnetic anisotropy or non-magnetism.

17. An electronic device comprising:
the magnetoresistive element according to claim 1.
